(19) United States
(12) Patent Application Publication
(10) Pub. No.: US 2003/0064535 A1
(43) Pub. Date: Apr. 3, 2003

(54) Method of manufacturing a semiconductor device having a thin GaN material directly bonded to an optimized substrate

(76) Inventors: Francis J. Kub, Arnold, MD (US); Karl D. Hobart, Uppermarlboro, MD (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 09/964,546

(22) Filed: Sep. 28, 2001

(51) Int. Cl. H01L 21/00; H01L 21/265

(52) U.S. Cl. 438/22; 438/46; 438/520; 438/458

(57) ABSTRACT

A method for manufacturing an electronic device utilizing a thin GaN material is provided in which a GaN layer is epitaxially grown on a transfer substrate. A hydrogen ion implant layer is formed in the GaN layer. A handle substrate having desirable thermal or electrical conductivity is bonded to the transfer substrate having the GaN layer grown thereon. The joined structure is heated to split off the transfer substrate along the hydrogen ion implant layer, thereby resulting in an optimized substrate with GaN layer transferred thereto.

### STATEMENT REGARDING FEDERALLY SPONSORED RESEARCH

This invention was made by employees of the United States Government and may be manufactured and used by or for the Government for governmental purposes without the payment of any royalties.

### BACKGROUND OF THE INVENTION

1. Field of the Invention

The present invention relates to the manufacture of a semiconductor device which utilizes GaN material, and in particular, to a method of manufacturing a semiconductor device by first forming a GaN thin layer on a transfer substrate followed by hydrogen ion splitting to transfer a portion of the GaN thin layer to an optimized handle substrate.

2. Background of the Invention

Semiconductor devices often include GaN layers due to their electrical and optical properties. Such devices include a GaN PN junction and a GaN field effect transistors (FET). These semiconductor devices may be incorporated for use in such applications as a GaN laser, a GaN LED and a vertical conducting powered device.

Typically, GaN layers are grown on a sapphire growth substrate due to its inert characteristics and its inexpensive cost. GaN layers are grown and annealed on the sapphire growth substrate at around 500° C. to 1000° C. These temperatures provide conditions for growing a high quality, optimal epitaxial GaN layer. The sapphire growth substrate is able to withstand the growth and annealing temperatures.

However, sapphire is not an optimal substrate for semiconductor device performance as sapphire has a relatively poor thermal conductivity and tends to be electrically insulating. For example, GaN blue-green lasers, GaN LEDs, vertical conducting power switching devices, and vertical conducting microwave devices all require electrically conducting substrates, and GaN microwave powered devices require a high thermal conducting substrate.

The GaN layers are not grown on an optimized handle substrate such as a thermally conducting or electrically conducting substrate. At the 500° C. to 1000° C. epitaxial GaN layer annealing temperature, the optimized handle substrate and/or any circuits formed thereon could be damaged.

One disadvantage with current semiconductor devices having GaN layers formed on a sapphire substrate is that the sapphire has a relatively poor thermal conductivity and tends to be electrically insulating. Consequently, the semiconductor device formed thereon will have limited performance due to the non-optimal characteristics of the sapphire substrate.

An additional disadvantage with using sapphire as the growth substrate upon which GaN layers are grown is that the differences in thermal expansion between sapphire and GaN results in cracking of a thick epitaxial GaN layer growth.

### BRIEF SUMMARY OF THE INVENTION

In accordance with the present invention, a semiconductor manufacturing method is provided in which an epitaxially grown GaN layer is transferred from a transfer substrate to a preferable handle substrate. During the manufacturing process, the transfer substrate and handle substrate are bonded together to form a joined structure. The joined structure is split apart along a hydrogen ion implant layer formed in the epitaxial GaN layer thereby transferring a portion of the epitaxial GaN layer to the preferred handle substrate.

According to one aspect of the present invention, a method is provided for manufacturing an electronic device comprising the steps of growing an epitaxial GaN layer on a transfer substrate and implanting hydrogen ions in the epitaxial GaN layer. The implanted hydrogen ions form an intermediate hydrogen ion implant layer thereby defining a GaN layer transfer portion with a GaN top surface of the epitaxial GaN layer. The transfer substrate is bonded to a handle substrate to form a joined structure. The joined structure is heated to a temperature sufficient to split the joined structure along the hydrogen ion implant layer thereby transferring the GaN layer transfer portion to the handle substrate and to form a splitting surface on the GaN layer transfer portion.

According to another aspect of the present invention, a semiconductor device is provided comprising a device substrate and an epitaxial GaN layer having a crystalline structure defined by a transfer substrate upon which the epitaxial GaN layer was grown. A bond is formed between the epitaxial GaN layer and a device substrate.

One feature of the present invention concerns transferring a GaN layer formed on a transfer substrate optimal for GaN epitaxial growth to a handle substrate having optimal thermal and/or conductive properties. An optimal epitaxially grown GaN layer is first formed on the transfer substrate composed of material advantageous for GaN growth. The handle substrate is composed of material which provides desired thermal conductivity or electrical conductivity for the semiconductor device formed thereon.

An advantage of the present invention concerns the reuse of transfer substrates. After a portion of the GaN layer is transferred to the handle substrate, the transfer substrate may be reused for growing additional GaN layers which then may be transferred to an additional handle substrate.

An additional feature of the present invention concerns the use of hydrogen ion implanting and splitting of the GaN layer. This method provides for the separation of a joined handle substrate and transfer substrate without posing potential damage to the handle substrate or devices formed thereon. The hydrogen ion implantation splitting process allows for the separation of the GaN along the hydrogen ion implantation layer, for example, by heating the joined structure to a sufficient temperature which does not negatively affect the handle substrate or the devices formed thereon.

Further features and advantages of the present invention will be set forth in, or apparent from, the detailed description of preferred embodiments thereof which follows.

### BRIEF DESCRIPTION OF THE DRAWING

FIGS. 1(a)-1(d) are schematic sectional views of manufacturing processing steps to form an electronic device according to the present invention;

FIGS. 2(a)-2(d) are schematic sectional views of processing steps of a electronic device manufacturing method according to an alternative embodiment of the present invention;

FIG. 3(a)-3(d) are schematic sectional views illustrating various steps in yet another alternative embodiment of the present invention;

FIGS. 4(a)-4(d) are schematic sectional views illustrating various steps in an additional alternative method of manufacturing an electronic device of the present invention;

FIGS. 4(e)-4(j) are schematic sectional views illustrating further alternative processing steps to the method depicted in FIGS. 4(a)-4(d);

FIG. 5(a)-5(e) are schematic sectional views illustrating yet an additional alternative embodiment of the present invention;

FIGS. 6(a)-6(e) are schematic sectional views illustrating an additional alternative embodiment of the present invention; and

FIGS. 7(a)-7(g) are schematic sectional views illustrating the steps of yet an additional embodiment of a method of the present invention.

### DETAILED DESCRIPTION OF THE INVENTION

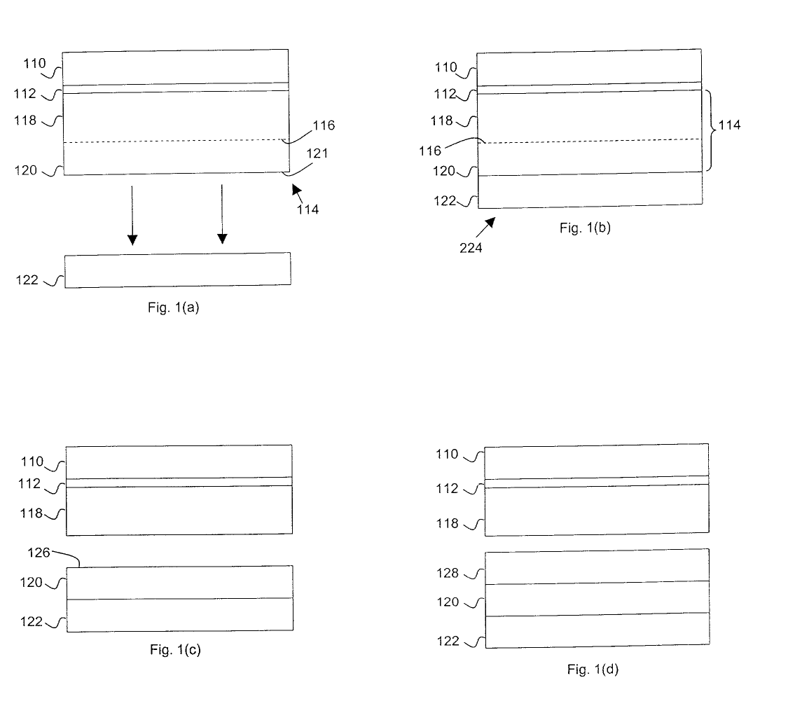

Referring generally to FIGS. 1(a)-1(d), depicted therein is a manufacturing process for forming a epitaxially grown GaN layer on a transfer substrate followed by transferring a portion of the GaN layer to an optimal, handle substrate. Referring now specifically to FIG. 1(a), a transfer substrate 110 is employed as a substrate upon which an epitaxial GaN layer 114 is grown. Optionally, the transfer substrate 110 may include a thin GaN layer 112 bonded thereon, upon which the epitaxial GaN layer 114 is grown.

Advantageously, transfer substrate 110 promotes epitaxial GaN growth under optimal growth conditions without damage to the transfer substrate 110. Thus, the transfer substrate 110 may be formed of such material which includes, but is not limited to, sapphire, SiC, poly-SiC, poly-SIC-single crystal SiC, or a cabonized silicon substrate. Advantageously, the transfer substrate 110 may be reused after a portion of the epitaxial GaN layer 114 is transferred to a handle substrate 122.

The quality of the epitaxial GaN layer 114 improves as the GaN epitaxial growth proceeds further away from the transfer substrate 110 surface. Due to a large lattice mismatch between epitaxial grown GaN and the transfer substrate 110, for example when composed of sapphire, there may be a reduced quality in the epitaxial GaN layer 114 grown closest to a sapphire transfer substrate 110. Thus, the thin GaN layer 112 provides for enhanced epitaxial GaN layer growth by spacing the epitaxial GaN layer 114 growth from the transfer substrate 110.

The highest quality epitaxial GaN layers 114 can be grown on a transfer substrate 110 formed of a SiC single crystal substrate. The SiC single crystal substrate typically has only approximately four percent mismatch between the SiC substrate and the epitaxial GaN layers 114 grown thereon.

Hydrogen ions are implanted in the epitaxial GaN layer 114 thereby forming an intermediate hydrogen ion implant layer 116. The hydrogen ion implant layer 116 divides the epitaxial GaN layer 114 into a GaN layer substrate portion 118 and a GaN layer transfer portion 120 with GaN top surface 121.

Optionally, after the epitaxial GaN growth, the GaN top surface 121 can be polished, e.g., by chemical mechanical polishing (CMP) to provide a desired roughness on GaN top surface 121. If such a polishing is desired, it is advantageous that the transfer substrate 110 be formed of a suitable material such as an ultra-flat sapphire substrate or other suitable material providing for the polishing step to occur. The polishing may be done either before or after hydrogen ion implantation.

The transfer substrate 110 with epitaxial GaN layer 114 grown thereon is bonded to a desired, handle substrate 122 as indicated by the arrows in FIG. 1(a) to form a joined structure 124 (FIG. 1(b)). The handle substrate 122 can be optimized for thermal conductivity, microwave properties, and electrical conductivity. Further, the handle substrate 122 can be optimized to have thermal expansion properties matched to epitaxial GaN so that thick epitaxial GaN layers can be grown thereon, reflective properties such as for a mirror of a GaN laser, or transparent properties for a GaN LED or combinations thereof.

Any of a number of bonding techniques may be used to form a bond between the GaN layer transfer portion 120 and the handle substrate 122. Such bonding techniques include the use of a spin-on-glass adhesive, a high temperature polymer, a graphite adhesive, and a high temperature braze. Further, a bonding interface may include a heavily doped polysilicon, a heavily doped silicon deposited on a refractory metal previously formed on the GaN top surface 121, a high melting temperature conductive polycrystalline layer and an amorphous semiconductor layer.

The joined structure 124 is heated to a sufficient temperature to split the epitaxial GaN layer 114 along the hydrogen ion implant layer 116 as shown in FIG. 1(c). Typically, a temperature of 500° C. to 800° C. is sufficient to split the epitaxial GaN layer 114. A GaN layer transfer portion splitting surface 126 is generated from the epitaxial GaN layer 114 being split along the hydrogen ion implant layer 116.

Optionally, at this point, the GaN layer transfer portion splitting surface 126 may be polished and a further epitaxial GaN layer 128 may be formed on the polished surface (FIG. 1(d)).

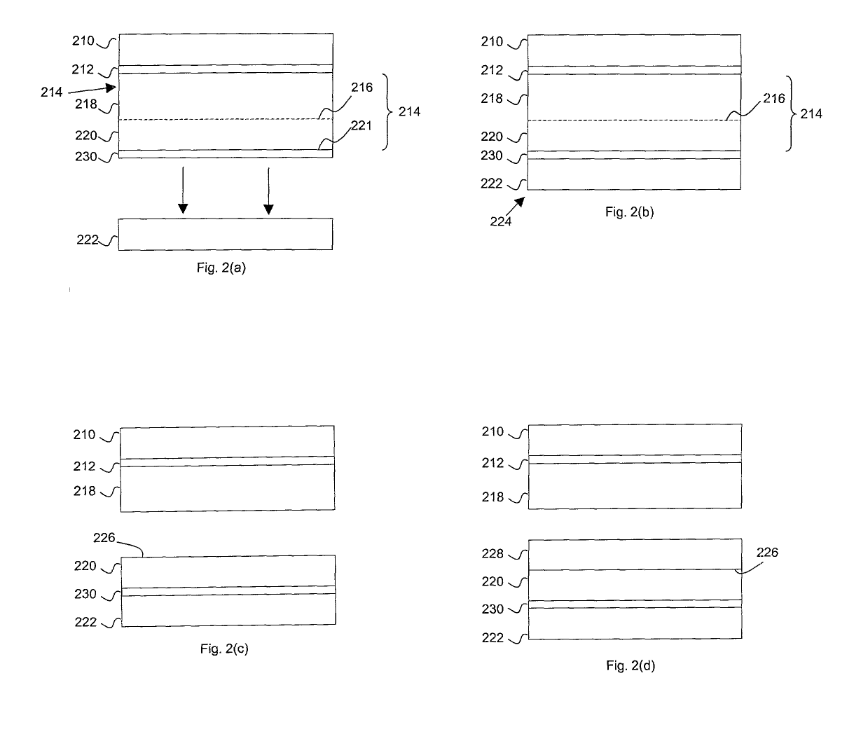

The general manufacturing method described above with reference to FIGS. 1(a)-1(d) may be modified and additional manufacturing processing steps or techniques added as necessary to form a desired electronic device having a thin GaN layer transferred and bonded to an optimized handle substrate. One such further alternative embodiment is described with reference to FIGS. 2(a)-2(d) which depict the processing step for growing an epitaxial GaN layer 214 on a transfer substrate 210 and then transferring the epitaxial GaN layer to a thermally conductive substrate, a microwave substrate, or substrate having a thermally expansion matched to GaN.

Referring now specifically to FIG. 2(a), a thin GaN layer 212 is bonded to a sapphire transfer substrate 210. A several micron thick layer of epitaxial GaN layer 214 is grown on the sapphire transfer substrate 210. Hydrogen ions are implanted into the epitaxial GaN layer 214 at a concentration of greater than 5×10¹⁶cm⁻² using a force of approximately 60 keV. As a result, hydrogen ion implant layer 216 is formed within the epitaxial GaN layer 214 thereby defining a GaN layer substrate portion 218 and El GaN transfer portion 220 with GaN top surface 221.

A spin-on-glass layer 230 is spun on the GaN top surface 221. An optimized handle substrate 222 is bonded to the spin-on-glass layer 230 to form joined structure 224 (FIG. 2(b)). The handle substrate 222 may be a thermally conductive, microwave conductive, or a thermal expansion matched substrate to that of GaN. Depending on the desired properties of the handle substrate 222, the handle substrate 222 can be made of a material such as silicon, AlN, poly-SiC, SiC or other suitable material known to one of ordinary skill.

Heat is applied to the joined structure 224 to split-off the sapphire substrate 210 with GaN layer substrate portion 218 formed thereon from the handle substrate 222 with the GaN layer transfer portion 220 transferred thereon (FIG. 2(c)). Optimally, the joined structure 224 is heated to between 500° C. and 800° C. to split the joined 224 structure along the hydrogen ion implant layer 216.

Optionally, GaN layer transfer portion splitting surface 226 can be polished using for example CMP or other techniques known in the art and a further epitaxial GaN layer 228 may be formed on the polished surface of the GaN layer transfer portion 220 (FIG. 2(d)).

The spin-on-glass layer 230 should be thin as to not induce too much thermal impedance between the handle substrate 222 and the GaN transfer portion 220. The spin-on-glass layer 230 impedes vertical current conduction, i.e., current conduction between the handle substrate 222 and the GaN transfer portion 220.

While the spin-on-glass layer 230 is spun on GaN top surface 221, alternatively, a spin-on-glass layer can be spun on the handle substrate 222 or spun on both the GaN top surface 221 and the handle substrate 222.

As will be apparent to one of ordinary skill in the art, the method depicted in FIGS. 2(a)-2(d) is preferable for applications which do not require a vertical current conduction through the handle substrate 222.

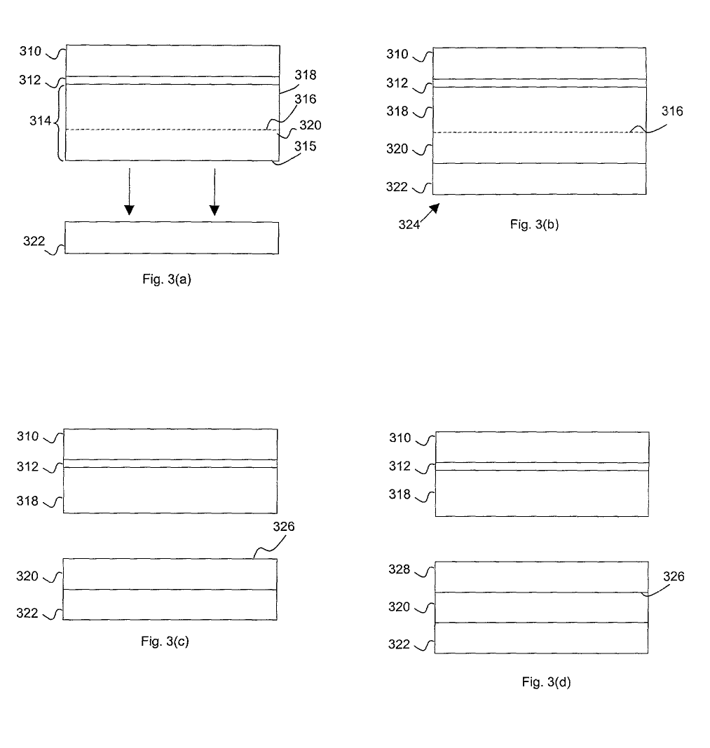

Turning now to FIGS. 3(a)-3(d), in another alternative embodiment, a semiconductor manufacturing method is provided which provides for a vertical current conduction through a desired or optimal handle substrate.

Referring now specifically to FIG. 3(a), a thin GaN layer 312 is bonded to an ultra-flat sapphire transfer substrate 310. A several micron thick layer of epitaxial GaN layer 314 is epitaxially grown on the thin GaN layer 312. An intermediate hydrogen ion implant layer 316 is formed within GaN layer 314 thereby defining GaN layer substrate portion 318 and GaN layer transfer portion 320. Hydrogen ion implantation is provided at a concentration greater than 5×10¹⁶ cm ⁻² using approximately 60 keV resulting in a peak implant of approximately 500 nm into the GaN layer 314. Optionally, the GaN top surface 321 is polished to obtain a surface roughness to less than 10 A.

GaN layer transfer portion 320 is directly bonded to an electrically conductive handle substrate 322 to form joined structure 324 (FIG. 3(b)). Handle substrate 322 can be silicon, poly-SiC, SiC, GaAs or any other suitable substrate known in the art. The joined structure 324 is heated to between 500° C. and 800° C. to split-off the sapphire substrate 310 with GaN substrate portion 318 formed thereon at the location of the peak of the hydrogen ion implant, i.e., along hydrogen ion implant layer 316 (FIG. (c)). Optionally, if necessary, a GaN layer transfer portion splitting surface 326 is polished using any conventional method known to one of ordinary skill in the art. If desired, a further GaN layer 328 is epitaxially grown on the polished GaN layer transfer portion splitting surface 326 (FIG. 3(d)).

The resulting structure of the electrically conductive handle substrate 322 with the GaN layers 320, 328 formed thereon provide for vertical current conduction i.e., current conduction between GaN layer 328 and substrate 322.

The transfer substrate 310 with the GaN layer substrate portion 318 grown thereon can be reused i.e., further GaN layers may be epitaxially grown on the GaN layer substrate portion 318.

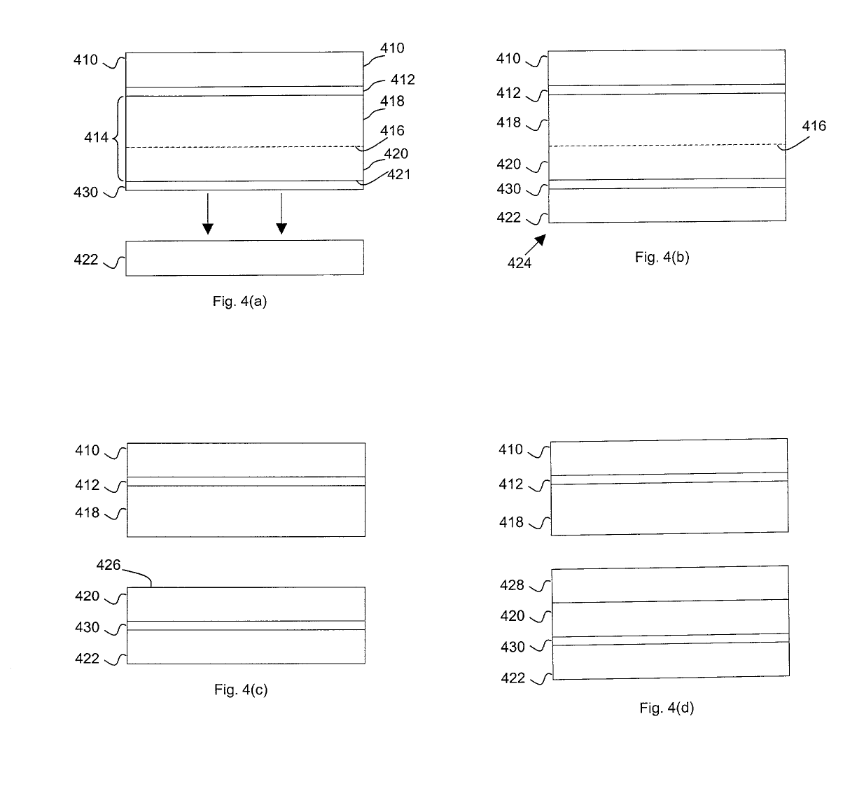

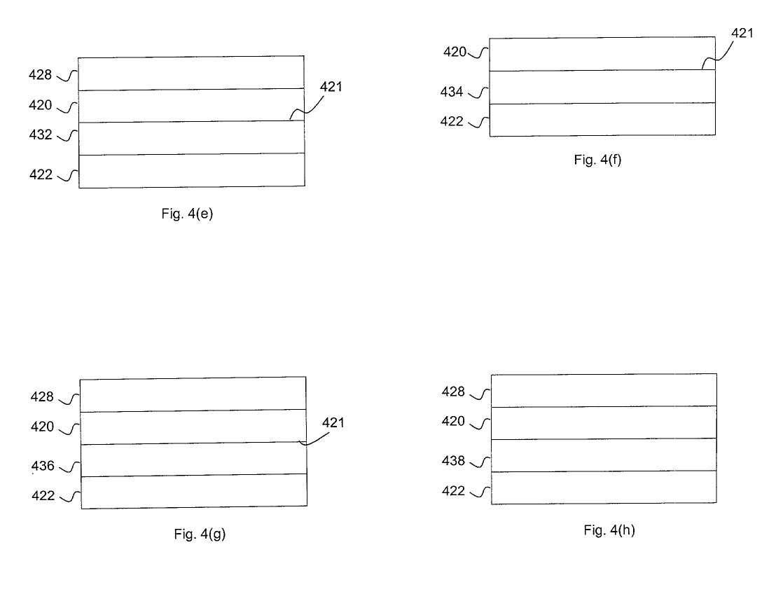

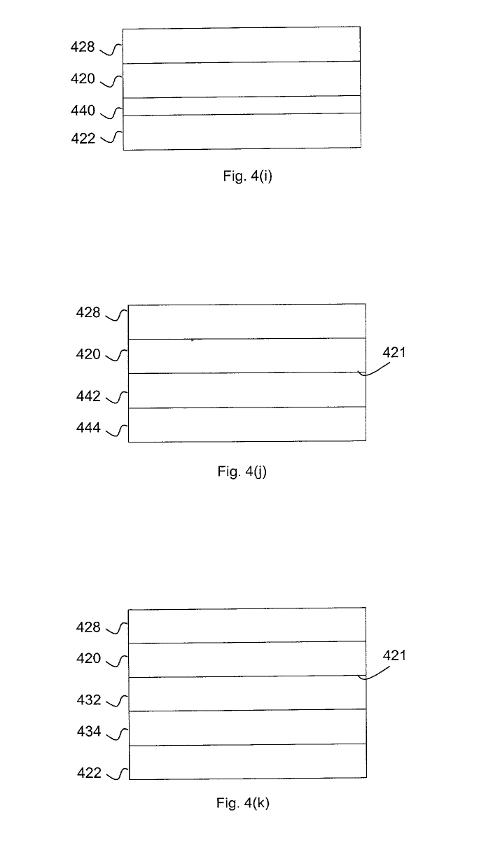

Turning now to FIGS. 4(a)-4(d), a semiconductor manufacturing process is depicted for a Bragg refractor for a vertical cavity laser grown on a GaN layer 414 or other suitable transfer substrate 410 prior to direct bonding of the transfer substrate and a handle substrate. Referring specifically now to FIG. 4(a), a several micron thick layer of epitaxial GaN layer 414 is grown on a thin GaN layer 412 bonded to an ultra-flat sapphire transfer substrate 410. GaN top surface 421 is polished as necessary to obtain a roughness of less than 10 A.

A superlattice Bragg refractor 430 is formed on the polished GaN top surface 421. The Bragg refractor 430 may be formed of GaN and InGaN or AlN layers. Alternatively, a Bragg refractor may be formed from deposited dielectric layers and a semiconductor.

Hydrogen ion implantation is provided at a concentration greater than 5×10¹⁶ cm⁻² using approximately 60 keV resulting in a peak implantation of approximately 500 nm into the GaN layer 414 and producing hydrogen ion implant layer 416.

The transfer substrate 410 with layers formed thereon is directly bonded to an electrically conductive handle substrate 422 resulting in a joined structure 424 (FIG. 4(b)). The handle substrate 422 may be composed of any suitable conductive material which may include, but is not limited to, silicon, poly-SiC, SiC, and GaAs. The joined structure 424 is heated to between 500° C. and 800° C. to split-off the sapphire substrate 410 with GaN layer substrate portion 418 grown thereon from the handle substrate 422 with GaN layer transfer portion 420 transferred thereon (FIG. 4(c)).

Optionally, GaN layer transfer portion splitting surface 426 may be polished to provide an appropriate surface for further epitaxial layer growth if desired. Subsequently, a further epitaxial layer 428 may be grown on the polished splitting surface 426 (FIG. 4(d)).

The handle substrate 422 with layers transferred thereon may be used to form a desired electronic device. For example, a vertical cavity laser may be formed using handle substrate 422 with layers transferred thereon.

While FIG. 4(a) depicts the Bragg reflector 430 first formed on the GaN layer 414 of the transfer substrate 410, the Bragg reflector can be first formed on the handle substrate 422.

In a further embodiment of the manufacturing method depicted in FIGS. 4(a)-4(d), a refractory metal 432 is deposited on GaN surface 421 rather than a Bragg refractor (FIG. 4(e)). A direct bond is then made between the refractory metal 432 and the electrically conductive handle substrate 422. Optionally, the GaN surface 421 has small surface roughness in order to provide a suitable surface upon which the refractory metal 432 is deposited. The refractory metal 432 may be polished to a surface roughness of less than one nm thereby allowing the refractory metal 432 to be bonded to the handle substrate 422.

The refractory metal 432 may act as a mirror for use in a vertical cavity laser. Further, the refractory metal 432 is suitable for a 1000C annealing temperature required for epitaxial GaN layer growth.

FIG. 4(f) depicts another alternative embodiment to the one of FIGS. 4(a)-4(d), in which a heavily doped polysilicon 434 is deposited on the GaN top surface 421. The polysilicon layer 434 can be polished using CMP to produce a small surface roughness which can then be directly bonded to the an electrically conductive handle substrate 422.

Referring now to FIG. 4(g), in an additional alternative embodiment, a deposited layer 436 of either a high melting temperature conductive polycrystalline or amorphous semiconductor material is formed on the GaN top surface 421. The deposited layer 436 is polished and bonded to the handle substrate 422. Alternatively, a refractory metal (not shown) may be deposited on the GaN top surface 421 upon which the deposited layer 436 of polycrystalline or amorphous semiconductor material is deposited.

Referring now to FIG. 4(h), in an additional alternative embodiment, a high temperature electrically conductive polymer 438 is used as an electrically conductive adhesive. The electrically conductive polymer 438 may comprise such material as a thallium doped polymer which turns into a thallium doped amorphous carbon layer when heated to an appropriate temperature.

Referring now to FIG. 4(i), graphite adhesive 440 is used to provide an electrical bond between the GaN layer 420 and the handle substrate 422.

Referring now to FIG. 40), the bond between the GaN layer 420 and the handle substrate 422 may comprise a high temperature braze 442.

Referring now to FIG. 4(k), in yet an alternative embodiment, a heavily doped polysilicon layer 434 is deposited on a refractory metal layer 432 formed on the GaN top surface 421.

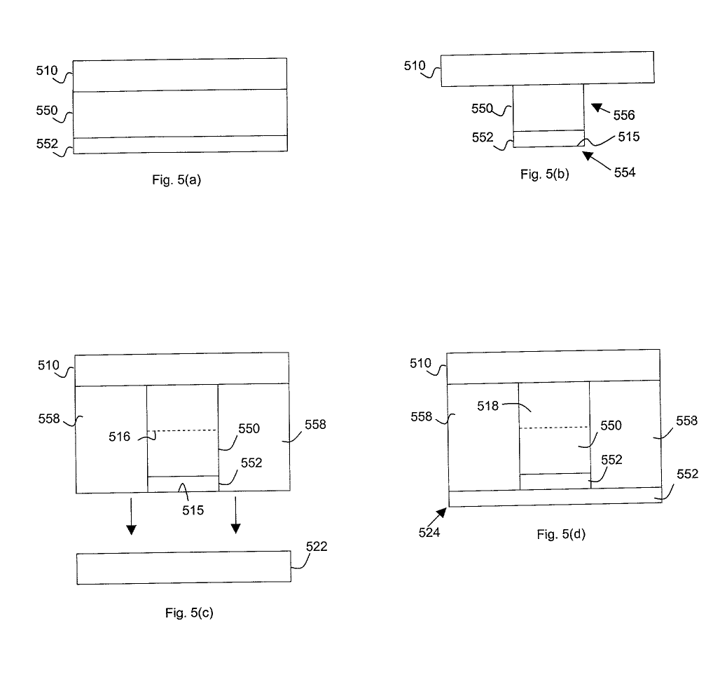

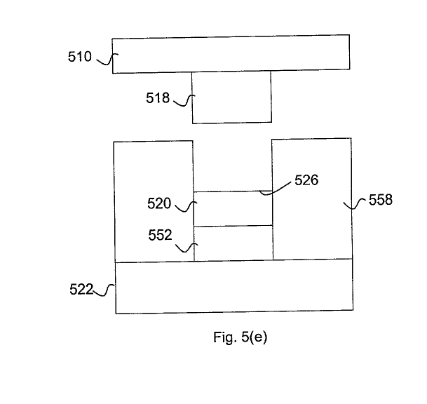

Turning now to FIG. 5(a)-5(e), in an alternative embodiment, an initial epitaxial GaN growth is provided on a sapphire substrate 510 forming a P-type layer 550 and an N-type layer 552. As a result, a PN junction 556 may be formed without any additional GaN growth on an optimized handle substrate 522 (FIG. 5(b)). Any of the bonding methods described above with reference to FIGS. 4(a)-4(j) may be used to bond the transfer substrate 510 with layers formed thereon to the handle substrate 522.

Referring now specifically to FIG. 5(a), approximately a one micron thick P-type epitaxial GaN layer 550 and a several micron thick lay N-type epitaxial GaN layer 552 are grown on an ultra-flat sapphire transfer substrate 510. Optionally, photolithography is used to define mesa 554 and an RIE etch is used to form a PN junction 556 (FIG. 5(b)). Optionally, the mesa 554 is isolated using an insulating layer such as oxide layer 558 which is planarized using CMP to the top surface of the GaN PN junction mesa 554 (FIG. 5(c)).

Alternatively, the mesa 554 can be bonded to an optimized handle substrate directly without the addition of the oxide layer 558 or other suitable insulator.

The GaN top surface 521 is polished as necessary to obtain a surface roughness of less than 10 A with care that a portion of the P-type GaN layer 552 remains (FIG. 5(c)). Hydrogen ion implantation is provided at a concentration of greater than 5×10¹⁶ cm⁻² using 160 keV to provide a peak hydrogen ion implant of approximately 1500 nm into the epitaxial GaN layers 550, 552 to form a hydrogen ion implant layer 516. The hydrogen implantation process can be performed before or after the GaN top surface polishing.

A direct bond is formed between the P-type GaN layer 522 and the electrically conductive handle substrate 522 to form a joined structure 524 (FIG. 5(d)). Handle substrate 522 may be formed of silicon, poly-SiC, SiC, and GaAs. Any of the approaches previously described with reference to the embodiments of FIG. 4 may be used to form the electrically conductive bond.

The joined structure 524 is heated to a temperature between 500° C. and 800° C. to split-off the transfer substrate 510 with GaN layer substrate portion 518 formed thereon (FIG. 5(e)).

Optionally, a GaN layer transfer portion splitting surface 526 may be polished and a further epitaxial GaN layer (now shown) grown thereon (FIG. 5(e)). The resulting handle substrate 522 with layers formed thereon may be used to form a desired PN junction device, for example a GaN laser.

Optionally, a Bragg reflector mirror (not shown) may be formed on the GaN top surface 521 (FIG. 5(b)), on the handle substrate 522 (FIG. 5(c)) or on the GaN layer top portion splitting surface 526 (FIG. 5(e)).

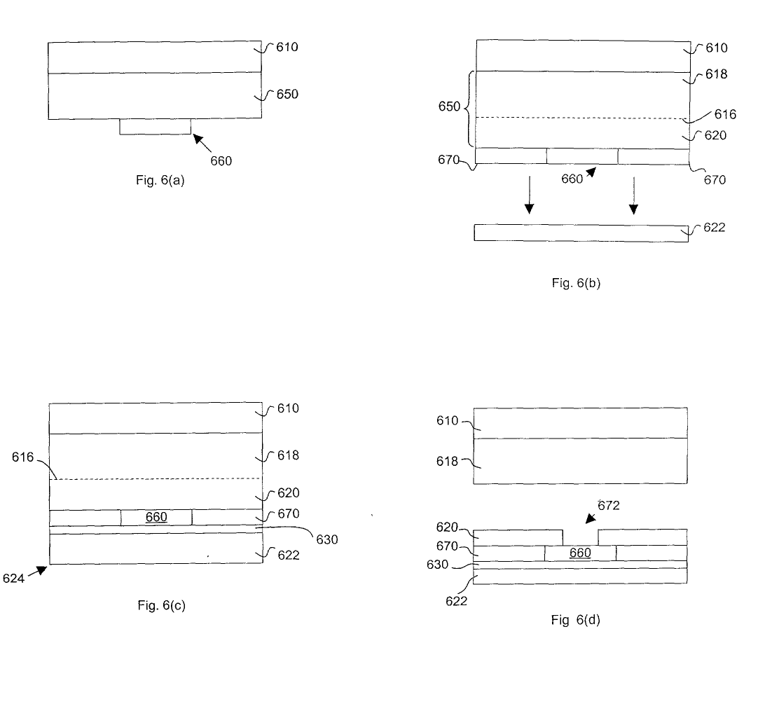

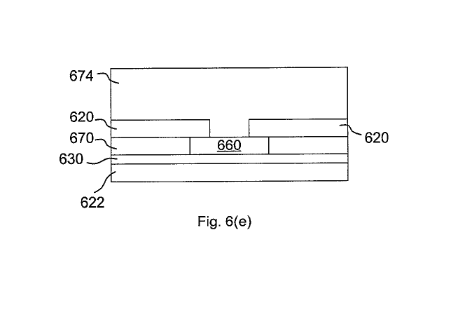

Turning now to FIGS. 6(a)-6(e), in yet an alternative embodiment, a semiconductor manufacturing method is provided to form a lateral GaN FET device 660 on a transfer substrate 610 having a epitaxial GaN layer 650 grown thereon and then transferred to an optimized handle substrate 622.

Referring now specifically to FIG. 6(a), a several micron thick layer N-type layer of epitaxial GaN layer 650 is grown on an ultra-flat sapphire substrate 610. A FET device labeled 660 is formed on the epitaxial GaN layer 650. Optionally, a first level of metal interconnections (not shown) can be formed on the transfer substrate 610.

A dielectric layer 670 is deposited over the FET device 660 and planarized (FIG. 6(b)). Hydrogen ion implantation is provided at a concentration of greater than 5×10¹⁶ cm⁻² using approximately 160 keV to provide a peak implant at approximately 1500 nm into the GaN layer 650, thereby forming an intermediate hydrogen ion implant layer 616.

A spin-on-glass adhesive layer 630 is used to directly bond the transfer substrate 610 to a thermally conductive, electrically insulating, handle substrate 622 resulting in a joined structure 624 (FIG. 6(c)). Spin-on-glass adhesive layer 630 may be either spun on handle substrate 622 or on planarized dielectric layer 670. Handle substrate 622 may be a poly-SiC, SiC, or a GaAs substrate.

The joined structure 624 is heated to between 500° C. and 800° C. to split off the transfer substrate 610 along the hydrogen ion implant layer 616 (FIG. 6(d)).

Photolithography and RIE are used to form a via 672 to the source/drains or first metal interconnects (not shown) of FET 660 (FIG. 6(d)). A dielectric layer 674 is deposited in the via 670 and on the GaN transfer portion 620 to thereby allowing for multiple layer interconnects (FIG. 6(e)).

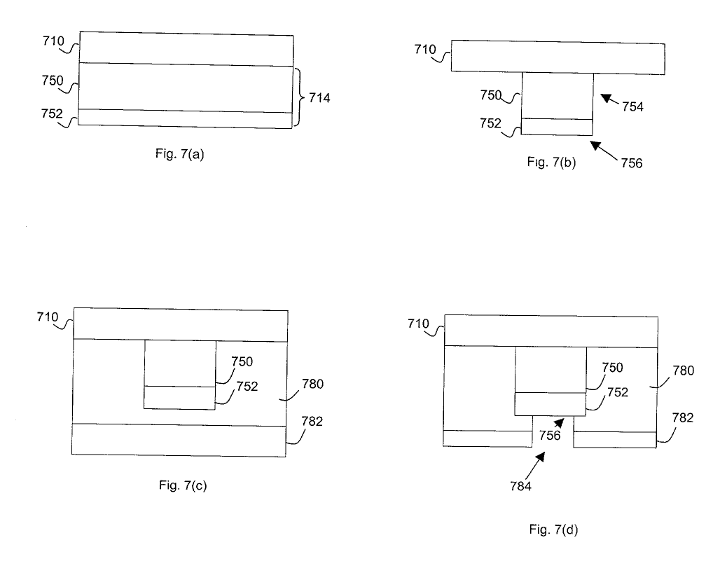

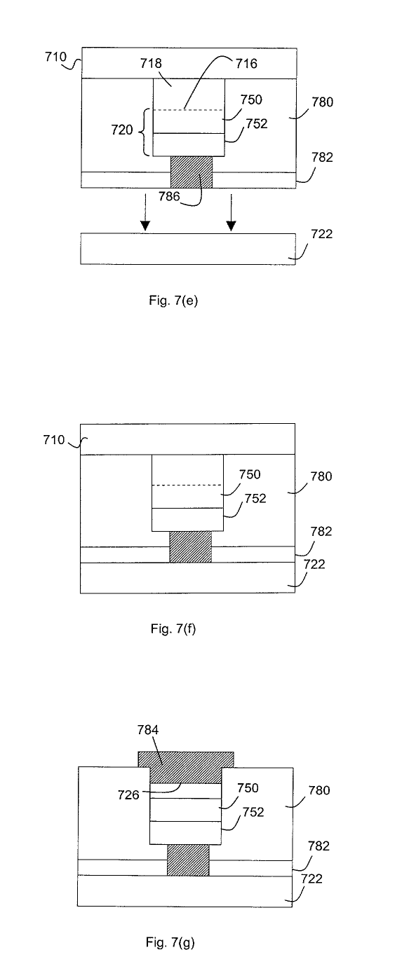

Turning now to FIGS. 7(a)-7(e), a semiconductor manufacturing process is depicted for forming a GaN LED device, a side-emitting laser, or a vertical cavity laser device first formed on a sapphire transfer substrate 710 and then transferring the GaN device to an appropriate conductive handle substrate 722.

Referring now specifically to FIG. 7(a), an N-type epitaxial GaN layer 750 and a P-type GaN layer 752 are grown on an ultra-flat, sapphire transfer substrate 710. Optionally, a Bragg reflector may be formed on the P-type GaN layer 752.

Photolithography is used to define a mesa 754 having a several micron thick N-type layer and approximately a one micron thick P-type layer 752 (FIG. 7(b)). A lateral oxide confining layer 780 is formed on the transfer substrate 710 (FIG. 7(c)). A dielectric layer 782 is deposited on the oxide layer 780 and CMP is used to planarize the deposited dielectric 782.

Photolithography and etching are used to define via 784 through the dielectric layer 782 to the top of PN junction 756 (FIG. 7(d)).

A metal layer 786 is deposited in via 784 to contact the top of PN junction 756 (FIG. 7(e)). The metal 786 may be composed of a suitable material that can withstand the temperatures necessary for hydrogen ion implant layer splitting of the GaN layer 714. For example, the metal layer 786 may be tungsten or Molybdenum. Optionally, the surface of the metal layer 786 can be polished.

Hydrogen ion implantation is provided at a concentration greater than 5×10¹⁶ cm⁻² using approximately 200 keV, thereby providing a peak hydrogen ion implant of approximately 200 nm into the GaN layer 714 so that the peak of the hydrogen implant lies within the N-type substrate 750. As a result, the hydrogen ion implant layer 716 divides the GaN layer 714 into a GaN substrate portion 718 and a GaN transfer portion 720.

The transfer substrate 710 is directly bonded to an electrically conductive handle substrate 722 formed of silicon poly-SiC, SiC, GaAs or other suitable electrically conductive substrate material. As a result of the direct bond, a joined structure 724 is generated (FIG. 7(f)). Any of the approaches described above for producing an electrically conductive bond may be used here. Further, the electrically conductive substrate 722 may have a Bragg reflector (not shown) formed thereon.

The joined structure is heated to between 500° C. and 800° C. to split-off the transfer substrate 710 with layers formed thereon at the hydrogen ion implant layer 716 (FIG. 7(g)).

Optionally, a Bragg refractor (not shown) for use in a vertical cavity laser may be formed on the GaN surface 726. A metal ohmic contact 784 is formed on top of the GaN layer 750.

Any of a number of well know manufacturing methods to one of ordinary skill in the art may be used to form a side-emitting or a vertical cavity laser using substrate 722 with the various layers depicted in FIG. 7(g) formed thereon.

As is apparent now to one of ordinary skill in the art, the various embodiments of the present invention provide advantages over previous GaN device manufacturing methods. For example, the present invention provides for the reuse of expensive sapphire or other transfer substrates.

In addition, an optimal transfer substrate may be selected which is preferable for epitaxial GaN growth which can then be transferred to an optimal handle substrate optimized for thermal or electrical conductivity. A superior epitaxially grown GaN layer can now be first formed on an optimal growth substrate and then transferred to an optimal handle substrate. As a result, a superior epitaxially grown GaN layer which could only be grown on an expensive, yet thermally and electrically nonconductive substrate, may now be provided on an optimal thermal or electrically conductive substrate by transferring the epitaxially grown GaN layer from the optimal transfer substrate to the optimal handle substrate.

A further advantage is provided by incorporating the optimal handle substrate with epitaxially grown GaN layers for use in an electronic device. A superior electronic device is now provided by incorporating an optimum epitaxial GaN layer disposed on an optimal thermal or electrically conductive substrate layer. For example, an optimized substrate can provide excellent thermal conductivity or electrical conductivity whereas an optimal growth substrate for forming an epitaxial GaN layer tends to provide poor thermal conductivity and is electrically insulating. Thus an electronic device which utilizes a GaN layer such as a GaN blue-green laser, a GaN LED, a vertical conducting power switch devices and a vertical conducting microwave device requiring an electrical conducting substrate all will benefit from using a GaN layer disposed on an optimal substrate. Further devices such as a GaN microwave powered device which requires high thermal conductivity will benefit from an optimal substrate providing such a conductivity.

Although the invention has been described above in relation to preferred embodiments thereof, it will be understood by those skilled in the art that variations and modifications can be effected in these preferred embodiments without departing from the scope and spirit of the invention.

What is claimed is:

1. A method of manufacturing an electronic device, said method comprising the steps of:
growing an epitaxial GaN layer on a transfer substrate;
implanting hydrogen ions in the epitaxial GaN layer to form therein an intermediate hydrogen ion implant layer, thereby defining a GaN layer transfer portion of the epitaxial GaN layer, the GaN layer transfer portion having a GaN top surface;
bonding the transfer substrate to a handle substrate to form a joined structure; and
heating the joined structure to a temperature sufficient to split the joined structure along the hydrogen ion implant layer so as to transfer the GaN layer transfer portion to the handle substrate and to form a splitting surface on the GaN layer transfer portion.

2. The method of claim 1, wherein the handle substrate comprises a thermally conductive material.

3. The method of claim 2, wherein the thermally conductive material comprises one of silicon, poly-SiC, and SiC.

4. The method of claim 1, wherein said bonding step comprises:
forming a spin-on-glass layer on the GaN top surface; and
bonding the spin-on-glass layer to a bonding surface of the handle substrate.

5. The method of claim 1, wherein said bonding step comprises:
forming a spin-on-glass layer on a bonding surface of the handle substrate layer; and
bonding the spin-on-glass layer to the GaN top surface.

6. The method of claim 1, further comprising:
polishing the splitting surface of the GaN transfer portion to form a polished surface; and
growing a further epitaxial GaN layer on the polished surface.

7. The method of claim 1, wherein said heating step comprises heating the joined structure to between 500° C. and 800° C.

8. The method of claim 1, wherein the transfer substrate comprises one of sapphire and SiC.

9. The method of claim 1, further comprising polishing the GaN top surface to provide a desired roughness prior to said bonding step.

10. The method of claim 1, wherein the handle substrate comprises an electrical conductive substrate and said bonding step comprises directly bonding the handle substrate to the GaN layer transfer portion.

11. The method of claim 10, wherein the transfer substrate comprises an ultra-thin sapphire substrate.

12. The method of claim 1, further comprising polishing a bonding surface of the handle substrate to obtain a desired roughness prior to said bonding step.

13. The method of claim 1, wherein the handle substrate comprises an electrically conductive substrate and said bonding step comprises:
forming a Bragg reflector layer on the GaN top surface; and
bonding the Bragg reflector layer to a bonding surface of the handle substrate.

14. The method of claim 1, wherein the handle substrate comprises an electrically conductive substrate and said bonding step comprises:
forming a Bragg reflector layer on the handle substrate layer; and
bonding the Bragg reflector layer to the GaN top surface.

15. The method of claim 1, wherein the handle substrate comprises an electrically conductive substrate and said bonding step comprises:
depositing a refractory metal layer on the GaN top surface; and
bonding the handle substrate to the refractory metal layer.

16. The method of claim 1, wherein the handle substrate comprises an electrically conductive substrate and said bonding step comprises:
depositing a doped polysilicon layer on the GaN top surface;
polishing the doped polysilicon layer using CMP to form a polished polysilicon surface; and
bonding the handle substrate to the polished polysilicon surface.

17. The method of claim 1, wherein the handle substrate comprises an electrically conductive substrate and said bonding step comprises:
depositing a refractory metal layer on the GaN top surface;
depositing a doped polysilicon layer on the refractory metal layer;
polishing the doped polysilicon layer using CMP to form a polished polysilicon surface; and
bonding the handle substrate to the polished polysilicon surface.

18. The method of claim 1, wherein the handle substrate comprises an electrically conductive substrate and said bonding step comprises:
depositing layers of one of a high melting temperature conductive polycrystalline layer and an amorphous semiconductor layer on the GaN top surface;
polishing the layers deposited on the GaN top surface to form a polished surface; and
bonding the handle substrate to the polished surface.

19. The method of claim 1, wherein the handle substrate comprises an electrically conductive substrate and said bonding step comprises:
depositing a refractory metal layer on the GaN top surface;
depositing layers of one of a high melting temperature conductive polycrystalline layer and an amorphous semiconductor layer on the refractory metal layer;
polishing the layers deposited on the GaN top surface to form a polished surface; and
bonding the handle substrate to the polished surface.

20. The method of claim 1, wherein the handle substrate comprises an electrically conductive substrate and said bonding step comprises:
forming a high temperature electrically conductive polymer adhesive layer on the GaN top surface; and
bonding the handle substrate to the adhesive layer.

21. The method of claim 1, wherein the handle substrate comprises an electrically conductive substrate and said bonding step comprises:
forming a graphite adhesive layer on the GaN top surface; and
bonding the handle substrate to the graphite layer.

22. The method of claim 1, wherein the handle substrate comprises an electrically conductive substrate and said bonding step comprises high temperature brazing to bond the GaN layer transfer portion to the handle substrate.

23. The method of claim 1, wherein:
said growing an epitaxial GaN layer step comprises growing an N-type epitaxial GaN layer and a P-type epitaxial GaN layer on the transfer substrate;
said implanting hydrogen ions step comprises implanting hydrogen ions using sufficient force such that the hydrogen ion implant layer lies within the N-type layer; and
the handle substrate comprises an electrically conductive material; and
said method further comprising forming a PN junction device using the handle substrate with said layers formed thereon.

24. The method of claim 23, further comprising forming a PN junction mesa in the N-type layer and the P-type layer using photolithography and an RIE etch prior to said bonding step.

25. The method of claim 23, further comprising depositing an insulating layer over the PN junction mesa and planarizing the insulating layer.

26. The method of claim 1, wherein said growing an epitaxial GaN layer step comprises growing an N-type layer, and said implanting hydrogen ions step comprises implanting hydrogen ions using sufficient force such that the hydrogen implant layer lies within the N-type layer and the handle substrate comprises a thermally conductive, electrically insulation material; and said method further comprising:
fabricating a FET device having a source/drain on the GaN top surface;
depositing a dielectric layer over the FET device;
planarizing the dielectric layer;
said bonding step comprises using a spin-on-glass bonding adhesive to bond the handle substrate to the dielectric layer; and
forming a via through the GaN layer transfer portion from the GaN layer transfer portion splitting surface to the source/drain of the FET device.

27. The method of claim 1, wherein said growing an epitaxial GaN layer step comprises growing an N-type epitaxial GaN layer and a P-type epitaxial GaN layer on the transfer substrate; said implanting hydrogen ions step comprises implanting hydrogen ions using sufficient force such that the hydrogen ion implant layer lies within the N-type layer; and said method further comprising:
forming a mesa in the N-type layer and the P-type layer;
depositing a dielectric layer over the mesa;
planarizing the dielectric layer;
forming a via in the dielectric to the top PN junction; and
depositing a metal layer to contact the top PN junction; and
said bonding step comprises forming an electrically conductive bond between the handle substrate and the transfer substrate; and
forming a metal ohmic contact on the splitting surface of the GaN layer transfer portion.

28. The method of claim 27, further comprising forming a lateral oxide confining layer along vertical surfaces of the mesa.

29. A semiconductor device comprising:
a device substrate;
an epitaxial GaN layer having a crystalline structure defined by a transfer substrate upon which said epitaxial GaN layer was grown; and
a bond formed between said epitaxial GaN layer and said device substrate.

30. The semiconductor device of claim 29, wherein said device substrate comprises a thermally conductive material.

31. The semiconductor device of claim 29, wherein said bond comprises a spin-on-glass adhesive disposed between said device substrate and said epitaxial GaN layer.

32. The semiconductor device of claim 29, wherein the crystalline structure of said epitaxial GaN layer is defined by a said transfer substrate comprising one of sapphire and SiC.

33. The semiconductor device of claim 29, wherein said device substrate comprises an electrically conductive material.

34. The semiconductor device of claim 33, wherein said bond comprises a Bragg reflector layer disposed between said device substrate and said epitaxial GaN layer.

35. The semiconductor device of claim 33, wherein said bond comprises a refractory metal layer disposed between said device substrate and said epitaxial GaN layer.

36. The semiconductor device of claim 33, wherein said bond comprises a high temperature electrically conductive polymer adhesive layer disposed between said device substrate and said epitaxial GaN layer.

37. The semiconductor device of claim 29, wherein said device substrate comprises an electrically conductive material.

38. The semiconductor device of claim 29, further comprising a FET device formed on said epitaxial GaN layer.

39. The semiconductor device of claim 29, further comprising a PN junction device formed from said epitaxial GaN layer.
